(19) United States
(12) Patent Application Publication
(10) Pub. No.: US 2016/0159642 A1
(43) Pub. Date: Jun. 9, 2016

(54) STRESS ISOLATED MEMS DEVICE WITH ASIC AS CAP

(71) Applicant: FREESCALE SEMICONDUCTOR, INC., AUSTIN, TX (US)

(72) Inventors: STEPHEN R. HOOPER, MESA, AZ (US); CHAD S. DAWSON, QUEEN CREEK, AZ (US)

(21) Appl. No.: 14/564,340

(22) Filed: Dec. 9, 2014

(51) Int. Cl. B81B 7/00; B81C 1/00

(52) U.S. Cl. CPC B81B 7/0058; B81C 1/0023; B81B 2201/0264; B81B 2203/0118; B81B 2203/0127; B81B 2207/07

(57) ABSTRACT

A package includes a MEMS die and an integrated circuit (IC) die coupled to and stacked with the MEMS die. The MEMS die includes a substrate having a recess formed therein. A cantilevered platform structure of the MEMS die has a platform and an arm suspended over the recess, where the arm is fixed to the substrate. A MEMS device resides on the platform. The IC die is coupled to the MEMS die to serve as a protective cap for MEMS device. The MEMS die may be a pressure sensor die, and the MEMS device residing on the platform may be a sensor diaphragm. Thus, the IC die can include access vents extending through it for passage of a fluid from an external environment so that the sensor diaphragm can detect the pressure of the fluid.

### TECHNICAL FIELD OF THE INVENTION

The present invention relates generally to microelectromechanical systems (MEMS) devices. More specifically, the present invention relates to a MEMS die that utilizes an application specific integrated circuit (ASIC) as a cap.

### BACKGROUND OF THE INVENTION

Microelectromechanical systems (MEMS) devices are semiconductor devices with embedded mechanical components. MEMS devices include, for example, pressure sensors, accelerometers, gyroscopes, microphones, digital mirror displays, micro fluidic devices, and so forth. MEMS devices are used in a variety of products such as automobile airbag systems, control applications in automobiles, navigation, display systems, inkjet cartridges, and so forth.

There are significant challenges to be surmounted in the packaging of MEMS devices due at least in part to the necessity for the MEMS devices to interact with the outside environment, the fragility of many types of MEMS devices, and severe cost constraints. Indeed, many MEMS device applications require smaller size and low cost packaging to meet aggressive cost targets. Additionally, MEMS sensor applications require configurations that are largely impervious to package stress, which can otherwise cause instability of the MEMS device and output shifts in the MEMS device.

### BRIEF DESCRIPTION OF THE DRAWINGS

A more complete understanding of the present invention may be derived by referring to the detailed description and claims when considered in connection with the Figures, wherein like reference numbers refer to similar items throughout the Figures, the Figures are not necessarily drawn to scale, and:

FIG. 1 shows a side sectional view of a microelectromechanical systems (MEMS) package at section lines 1-1 of FIG. 2 in accordance with an embodiment;

FIG. 2 shows a top sectional view of the MEMS package at section lines 2-2 of FIG. 1 in accordance with an embodiment;

FIG. 3 shows a side sectional view of a MEMS package in accordance with another embodiment; and

FIG. 4 shows a flowchart of a fabrication process for fabricating either of the MEMS packages of FIGS. 1-3.

### DETAILED DESCRIPTION

Embodiments of the present invention entail fabrication methodology and a stress isolated MEMS device package that utilizes an application specific integrated circuit (ASIC) as a cap. In particular, a MEMS device is formed on a cantilevered platform structure which is connected to a bulk substrate at a sole attachment point. Such a configuration enables isolation of the MEMS device from outside stresses, such as packaging and/or thermal stresses. Additionally, the ASIC die is formed to include through-vias for electrical interconnection and access vents that allow air pressure to pass through to the MEMS device residing on the cantilevered platform structure. The access vents are created concurrently with and by the same process as the through-vias. Such a structural configuration and fabrication methodology enables an inexpensive packaging solution in a compact form factor that does not sacrifice part performance and that additionally does not require gel fill.

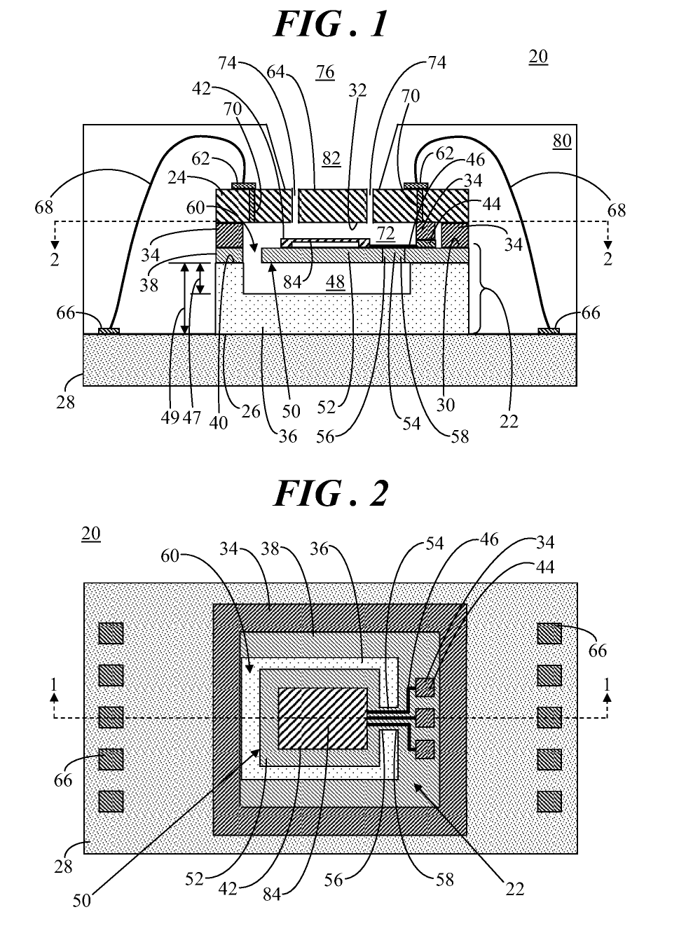

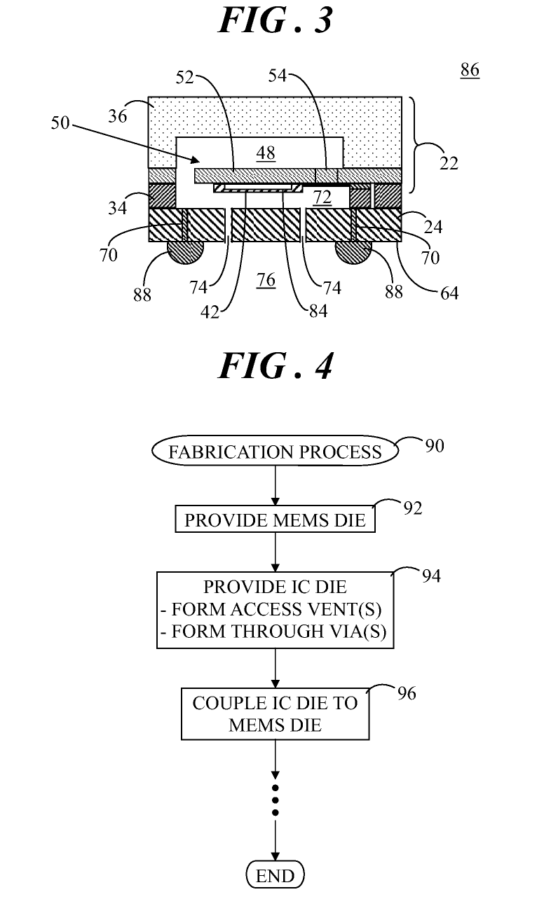

Referring now to FIGS. 1 and 2, FIG. 1 shows a side sectional view of a microelectromechanical systems (MEMS) pressure sensor package 20 at section lines 1-1 of FIG. 2 in accordance with an embodiment, and FIG. 2 shows a top sectional view of MEMS pressure sensor package 20 at section lines 2-2 of FIG. 1 in accordance with an embodiment. FIGS. 1-2 and subsequent FIG. 3 are illustrated using various shading and/or hatching to distinguish the different elements of MEMS pressure sensor package 20, as will be discussed below. These different elements within the structural layers may be produced utilizing current and upcoming micromachining techniques of depositing, patterning, etching, and so forth. It should further be understood that the use of relational terms, if any, such as first and second, top and bottom, and the like are used solely to distinguish one from another entity or action without necessarily requiring or implying any actual such relationship or order between such entities or actions.

Pressure sensor package 20 generally includes a MEMS die 22 and an application specific integrated circuit (ASIC) die 24 coupled to MEMS die 22. A first surface 26 of MEMS die 22 is coupled to a package substrate 28. A second surface 30 of MEMS die 22 is coupled to an inner surface 32 of ASIC die 24 in a stacked relationship via a bond material 34, where bonding may be, for example, aluminum-germanium bonding, copper-to-copper bonding, or any other suitable bonding process and bonding material.

MEMS die 22 includes generally includes a bulk substrate 36, a structural layer 38 fixed to a surface 40 of bulk substrate 36, and a MEMS device 42 formed on, or alternatively in, structural layer 38. MEMS die 22 may further include bond pads 44 on structural layer 38 and conductive traces 46 interconnected between MEMS device 42 and bond pads 44. Conductive traces 46 suitably electrically couple MEMS device 42 with bond pads 44.

In accordance with an embodiment, bulk substrate 36 has a recess 48 extending inwardly from surface 40 and partially through bulk substrate 36. As best seen in FIG. 1, recess 48 has a depth 47 that is less than a thickness 49 of bulk substrate 36. Structural layer 38 is fixed to surface 40 of bulk substrate 36 surrounding recess 48. A material portion of structural layer 38 is removed surrounding MEMS device 42 to form a cantilevered platform structure 50 at which MEMS device 42 resides. Thus, cantilevered platform structure 50 is formed in structural layer 38 and resides over recess 48.

Cantilevered platform structure 50 includes a platform 52 and an arm 54 extending from platform 52. A first end 56 of arm 54 is fixed to platform 52, and a second end 58 of arm 54 is fixed to bulk substrate 36. More particularly, second end 58 of arm 54 is fixed to bulk substrate 36 via an attachment of arm 54 to a portion of structural layer 38 fixed to surface 40 of bulk substrate 36. Thus, once the material portion of structural layer 38 is removed, an opening 60 extends through structural layer 38 and partially surrounds cantilevered platform structure 50. Accordingly, platform 52 and arm 54 are suspended over recess 48, with second end 58 of arm 54 being the sole attachment point of cantilevered platform structure 50 to the surrounding bulk substrate 36.

The illustrated configuration yields MEMS device 42 formed on a cantilevered platform structure 50 that is suspended over recess 48. Moreover, cantilevered platform structure 50 merely extends through the thickness of structural layer 38, instead of extending through the bulk, i.e., the entirety, of substrate 36. This cantilevered platform structure can achieve the benefits of improved package stress isolation, improved device performance, and a simplified package which reduces package costs. Although a pressure sensor die is discussed herein, it should be understood that MEMS device 42 may include a different MEMS sensor and/or more than one MEMS device.

In the illustrated embodiment, first electrical contacts 62 are provided on an outer surface 64 of ASIC die 24 and second electrical contacts 66 are provided on package substrate 28. Bond wires 68 interconnect first electrical contacts 62 with second electrical contacts 66. In this configuration, MEMS pressure sensor package 20 is a land grid array (LGA) version. LGA is a type of surface-mount packaging technology that typically includes contacts on the underside of the package, e.g., on the underside of package substrate 28 (not shown). The contacts can be electrically connected to a grid of contacts on a printed circuit board either by the use of a socket or by soldering directly to the board. Additionally, these contacts may be electrically connected to second electrical contacts 66 to form input to and/or output from ASIC die 24 and MEMS die 22.

Through-vias 70 may extend through ASIC die 24. The term “through-via” used herein denotes an electrically-conductive element, such as metallization formed through one or more dielectric layers and electrically coupling electrical conductors formed on different surfaces of ASIC die 24. In this example, through-vias 70 extend from inner surface 32 to outer surface 64 of ASIC die 24. In some configurations, through-vias 70 may be electrically connected to first electrical contacts 62. Additionally, or alternatively, through-vias 70 may be electrically interconnected with MEMS die 22. For example, electrically conductive bond material 34 may be used to form the electrical connection between bond pads 44 and bond pads (not shown) on ASIC 24, which are electrically connected with through-vias 70 (as shown in FIGS. 1 and 2).

ASIC die 24 is coupled to MEMS die 22 in a stacked relationship overlying cantilevered platform structure 50. Thus, ASIC die 24 serves as a lid or cap for MEMS device 42 residing on platform 52. Since ASIC die 24 serves as a cap for MEMS device 42 residing on platform 52, an additional capping substrate is not required as is typically utilized in the prior art. As such, savings can be achieved in terms of material costs for the capping substrate and process costs for attachment of the separate capping substrate. Additionally, the overall height of the structure is decreased relative to structures that might include a stacked configuration of an ASIC die, a MEMS die, and a capping substrate.

In an embodiment, bond material 34 may be of sufficient thickness such that ASIC die 24 is spaced apart from MEMS die 22 to provide a clearance space 72 between cantilevered platform structure 50 and ASIC die 24. In alternative arrangements, a spacer ring or another suitable structure may be used to produce clearance space 72 between cantilevered platform structure 50 and ASIC die 24. The use of ASIC die 24 as a cap may sufficiently protect MEMS device 42 from contaminants (e.g., water, oil, or dirt) external to MEMS package 20 to preclude the need for a protecting MEMS device 42 by covering it with a protective coating, such as a silicon gel, thereby achieving savings in terms of material costs and process costs.

One or more access vents 74 extend through ASIC die 24 from outer surface 64 to clearance space 72 so that MEMS device 42 residing on platform 52 is vented to an environment 76 external to MEMS pressure sensor package 20. As shown, access vents 74 are laterally displaced away from through-vias 70.

Through-vias 70 and access vents 74 may be formed with any known technique. In accordance with an embodiment, through-vias 70 and access vents 74 may be formed concurrently by, for example, etching ASIC die 24 to produce openings extending through the thickness of ASIC die 24. A subset of the openings are subsequently filled with a conductive material, for example, a metal material to form through-vias 70. A remainder of the openings are not filled with the conductive material. That is, the remainder of the openings are without the conductive material to yield access vents 74.

A molded body 80 (e.g., a coating or a mold compound, such as a plastic material) is formed at least partially around MEMS die 22 and around ASIC die 24. Molded body 80 fully encapsulates first and second electrical contacts 62, 66, and wire bonds 68. Molded body 80 may additionally cover or encapsulate through-vias 70. Molded body 80 sufficiently protects wire bonds 68 so that a gel fill, that may be used with prior art packages is not needed to protect them.

It should be readily observed that a void 82 is formed in molded body 80 so that molded body 80 does not cover access vents 74. Void 82 may be formed using any suitable technique. For example, void 82 may be formed by positioning a plug material (not shown) on outer surface 64 of ASIC die 24 over access vents 74 and applying the molding compound. After the molding compound has cured to form molded body 80, the plug material may be removed to expose access vents 74 to environment 76. It should be observed that ASIC die 24, bond wires 68, and molded body 80 are not shown in FIG. 2 in order to better visualize the underlying components.

In an embodiment, MEMS die 22 is a pressure sensor die and MEMS device 42 residing on platform 52 of cantilevered platform structure 50 comprises at least one pressure sensor diaphragm 84. As such, a fluid (e.g., air) can pass through ASIC die 24 from external environment 76 via access vents 74, reach clearance space 72, and act on pressure sensor diaphragm 84 (e.g., cause its deformation). For example, pressure sensor diaphragm 84 may move closer toward the underlying platform 52 formed in structural layer 38. The deformation of pressure sensor diaphragm 84 is detected via, for example, a change in capacitance between diaphragm 84 and platform 52, and this change is capacitance is used to determine the value of a pressure of the fluid in external environment 76.

FIG. 3 shows a side sectional view of a MEMS package 86 in accordance with another embodiment. As discussed in connection with FIGS. 1-2, MEMS package 20 is a molded land grid array configuration. In contrast, MEMS package 86 is a chip scale package (CSP) configuration. For clarity of description, the elements of MEMS package 86 that are equivalent to elements previously described in connection with MEMS package 20 of FIGS. 1 and 2 will share the same reference numerals and will share the same shading and/or hatching. A detailed description of those equivalent elements will not be repeated below for brevity.

In general, MEMS package 86 includes MEMS die 22 and ASIC die 24. MEMS die 22 includes bulk substrate 36 having recess 48 formed therein, cantilevered platform structure 50 having platform 52 and arm 54, and MEMS device 42 residing on platform 52. ASIC die 24 has one or more through-vias 70 and one or more access vents 74 formed therein. Again, ASIC die 24 is coupled to and in a stacked relationship with MEMS die 22. Additionally, ASIC die 24 is spaced apart from MEMS die 22 to provide clearance space 72 between MEMS device 42 and ASIC die 24.

MEMS package 86 does not include the package substrate 28, electrical contacts 62, 66, bond wires 68, and molded body 80 of MEMS package 20 (FIG. 1). Instead, ASIC die 24 serves as an interposer to which MEMS die 22 is coupled via bonding material 34 in a chip scale package configuration. Thus, MEMS package 86 includes electrical contacts 88 in the form of, for example, solder spheres, balls, or pads on outer surface 64 of ASIC die 24. Electrical contacts 88 may be electrically connected with through-vias 70.

In an exemplary embodiment, MEMS die 22 may be coupled to ASIC die 24 upon which electrical contacts 88 (pads or balls) are formed, e.g., ball grid array (BGA) packaging. In another exemplary embodiment, electrical contacts 88 may be etched or printed directly onto the silicon wafer while ASIC die 24 is part of a wafer containing a plurality of ASICs die 24 in a wafer-level packaging process. Since package substrate 28, electrical contacts 62, 66, bond wires 68, and molded body 80 (FIG. 1) are not needed in this configuration, the area of the resulting MEMS package 86 is generally equivalent to the area of MEMS die 22, thereby achieving a reduced form factor relative to MEMS package 20.

In use, MEMS package 86 can be placed on a printed circuit board (not shown) having pads arranged in a pattern that matches electrical contacts 88. MEMS package 86 is then heated to melt electrical contacts 88 or otherwise suitably processed to form soldered connections between MEMS package 86 and the PCB. It should be observed, therefore, that access vents 74 of MEMS package 86 would likely be facing the PCB. As such, a port (not shown) generally aligned with access vents 74 may extend through the PCB so that a fluid (e.g., air) can pass through the port and through ASIC die 24 from external environment 76 via access vents 74, reach clearance space 72, and act on pressure sensor diaphragm 84 (e.g., cause its deformation) to determine the value of a pressure of the fluid in external environment 76.

Referring to FIGS. 1 and 4, FIG. 4 shows a flowchart of a fabrication process 90 for fabricating either of the MEMS packages 20, 86 (FIGS. 1-3). Fabrication process 90 will be described in the context of fabricating a single MEMS packages, for example, MEMS package 20, for simplicity of illustration. However, those skilled in the art will recognize that a plurality of MEMS packages 20 may be formed concurrently in accordance with a wafer-level packaging process.

The execution of fabrication process 90 begins, in a block 92, by providing MEMS die 22. As described in detail above, MEMS die 22 includes package substrate 28, cantilevered platform structure 50, and MEMS device 42. Package substrate 28 has recess 48 formed therein, cantilevered platform structure 50 has platform 52 and arm 54 extending from platform 52, wherein platform 52 and arm 54 are suspended over recess 48. Arm 54 is fixed to substrate 28 and MEMS device 42 resides on platform 52. Again, MEMS die 22 may be a pressure sensor die and MEMS device 42 residing on platform 52 can include pressure sensor diaphragm 84.

In a block 94, ASIC die 24 is provided and one or more access vents 74 and one or more through-vias 70 are concurrently formed extending through ASIC die 24. As discussed above, through-vias 70 are laterally displaced away from access vents 74. Additionally, concurrently forming block 96 entails producing openings extending through ASIC die 24 and filling a subset of the openings with a conductive material to form through-vias 70, while leaving the remainder of the openings without the conductive material to yield access vents 74.

In a block 96, ASIC 24 is coupled to MEMS die 22 using bonding material 34. Coupling block is performed, in some embodiments, following the concurrent formation of access vents 74 and through-vias 70. Following coupling block 96, additional tasks associated with fabrication process 90 may be performed as represented by ellipses. These additional operations can include a wire bonding process to attach bond wires 68 to electrical contacts 62, 64, encapsulating to form molded body 80, testing, and so forth. Thereafter, fabrication process 90 ends.

As mentioned above, fabrication process 90 may be implemented at wafer-level. As such, block 92 would entail providing a MEMS wafer having a plurality of MEMS dies formed thereon. Block 94 would entail providing an IC wafer having a plurality of ASIC dies formed thereon, along with a plurality of access vents and through-vias. At block 96, the ASIC wafer would be coupled to the MEMS wafer to form a stacked wafer structure. Subsequent tasks would entail wire bonding, encapsulation, testing, and dicing the stacked wafer structure to produce a plurality of MEMS packages.

Embodiments described herein entail MEMS packages and methodology for fabricating the MEMS packages. In particular, a MEMS die includes a MEMS device formed on a cantilevered platform structure which is connected to a bulk substrate at a sole attachment point. Such a configuration enables isolation of the MEMS device from outside stresses, such as packaging and/or thermal stresses. Additionally, an application specific integrated circuit (ASIC) die is formed to include through-vias for electrical interconnection and access vents. The ASIC die is coupled to and in a stacked relationship with the MEMS die such that the ASIC die is spaced apart from the MEMS die to provide a clearance space between the MEMS device and the ASIC die. Thus, the ASIC die serves as a cap or lid for protecting the MEMS die. The access vents in the ASIC die allow air pressure to pass through to the MEMS device residing on the cantilevered platform structure. The access vents are created concurrently with and by the same process as the through-vias. Such a structural configuration and fabrication methodology enables an inexpensive packaging solution in a compact form factor that does not sacrifice part performance and that additionally does not require gel fill.

This disclosure is intended to explain how to fashion and use various embodiments in accordance with the invention rather than to limit the true, intended, and fair scope and spirit thereof. The foregoing description is not intended to be exhaustive or to limit the invention to the precise form disclosed. Modifications or variations are possible in light of the above teachings. The embodiment(s) was chosen and described to provide the best illustration of the principles of the invention and its practical application, and to enable one of ordinary skill in the art to utilize the invention in various embodiments and with various modifications as are suited to the particular use contemplated. All such modifications and variations are within the scope of the invention as determined by the appended claims, as may be amended during the pendency of this application for patent, and all equivalents thereof, when interpreted in accordance with the breadth to which they are fairly, legally, and equitably entitled.

1. A package comprising:
a microelectromechanical systems (MEMS) die including:
a substrate having a recess formed therein;
a cantilevered platform structure having a platform and an arm extending from said platform, wherein said platform and said arm are suspended over said recess, and said arm is fixed to said substrate; and
a MEMS device formed on said platform, wherein said MEMS device does not extend beyond an outer perimeter of said platform; and
an integrated circuit (IC) die coupled to and in a stacked relationship with said MEMS die, wherein said IC die is spaced apart from said MEMS die to provide a clearance space between said MEMS device and said IC die.

2. The package of claim 1 wherein said MEMS die comprises a pressure sensor, and said MEMS device comprises a pressure sensor diaphragm formed on and overlying said platform, said pressure sensor diaphragm being movable relative to said platform.

3. The package of claim 1 wherein said IC die is coupled to a surface of said substrate surrounding said recess.

4. The package of claim 1 further comprising through-vias extending through said IC die, said through-vias being electrically interconnected with said MEMS die.

5. The package of claim 4 further comprising electrical contacts provided on an outer surface of said IC die, wherein said through-vias are electrically connected with said electrical contacts.

6. The package of claim 5 wherein:
said electrical contacts are first electrical contacts;
said package further comprises a package substrate having second electrical contacts;
said MEMS die comprises a first surface and a second surface, said first surface being coupled to said package substrate; and
said IC die comprises an inner surface opposing said outer surface, said inner surface being coupled to said second surface of said MEMS die such that said MEMS die is interposed between said package substrate and said IC die, wherein bond wires interconnect said first electrical contacts with said second electrical contacts.

7. The package of claim 1 further comprising an access vent extending through said IC die from an exterior of said package to said clearance space so that said MEMS device is vented to an external environment via said access vent.

8. The package of claim 7 further comprising a through-via extending through said IC die, said through-via being electrically interconnected with said MEMS die, and said through-via being laterally displaced away from said access vent.

9. The package of claim 7 further comprising a molded body formed at least partially around said MEMS die and around said IC die, without covering said access vent.

10. The package of claim 1 further comprising a structural layer fixed to a surface of said substrate surrounding said recess, wherein said cantilevered platform structure extends from said structural layer to reside over said recess, and said arm is a sole attachment point of said platform to said structural layer.

11. The package of claim 1 wherein said recess has a depth that is less than a thickness of said substrate.

12. A package comprising:
a pressure sensor die including:
a substrate having a recess formed therein;
a cantilevered platform structure having a platform and an arm extending from said platform, wherein said platform and said arm are suspended over said recess, and said arm is fixed to said substrate; and
a pressure sensor formed on said platform that does not extend beyond an outer perimeter of said platform said pressure sensor including a pressure sensor diaphragm overlying said platform, said pressure sensor diaphragm being movable relative to said platform; and
an integrated circuit (IC) die coupled to and in a stacked relationship with said pressure sensor die, said IC die being spaced apart from said pressure sensor die to provide a clearance space between said pressure sensor diaphragm and said IC die, wherein said IC die includes:
an access vent extending through said IC die from an exterior of said package to said clearance space so that said pressure sensor diaphragm is vented to an external environment via said access vent; and
a through-via extending through said IC die, said through-via being electrically interconnected with said pressure sensor die, and said through-via being laterally displaced away from said access vent.

13. The package of claim 12 further comprising a structural layer fixed to a surface of said substrate surrounding said recess, wherein said IC die is coupled to said structural layer, said cantilevered platform structure extends from said structural layer to reside over said recess, and said arm is a sole attachment point of said platform to said structural layer.

14. The package of claim 12 further comprising electrical contacts provided on an outer surface of said IC die, wherein said through-via is electrically connected with said electrical contacts.

15. The package of claim 14 wherein:
said electrical contacts are first electrical contacts;
said package further comprises a package substrate having second electrical contacts;
said pressure sensor die comprises a first surface and a second surface, said first surface being coupled to said package substrate; and
said IC die comprises an inner surface opposing said outer surface, said inner surface being coupled to said second surface of said pressure sensor die such that said MEMS die is interposed between said package substrate and said IC die, wherein bond wires interconnect said first electrical contacts with said second electrical contacts.

16. The package of claim 14 further comprising a molded body formed at least partially around said pressure sensor and around said IC die without covering said access vent, wherein said molded body covers said through-via.

17-20. (canceled)
